(19) United States
(12) Patent Application Publication
(10) Pub. No.: US 2026/0239755 A1
(43) Pub. Date: Aug. 13, 2026

(54) SEMICONDUCTOR PACKAGE INCLUDING MOLDED ASSEMBLY OF COVER GLASS AND FRAME

(71) Applicant: Samsung Electronics Co., Ltd., Suwon-si (KR)

(72) Inventors: Soichiro TANAKA, Yokohama-shi (JP); Koji HAMAGUCHI, Yokohama-shi (JP)

(73) Assignee: Samsung Electronics Co., Ltd., Suwon-si (KR)

(21) Appl. No.: 19/409,158

(22) Filed: Dec. 4, 2025

(30) Foreign Application Priority Data
Feb. 13, 2025 (JP) 2025-021344

(51) Int. Cl. H10F 39/00

(52) U.S. Cl. CPC H10F 39/804; H10F 39/811

(57) ABSTRACT

The semiconductor package may include a substrate, a semiconductor chip stacked on a top surface side of the substrate and electrically connected to the substrate through a wire, a cover glass, and a frame on the substrate and holding the cover glass on the substrate. The frame has a cover glass holder holding an outer circumference of a top surface of the cover glass, and the cover glass and the frame are a molded assembly in which the top surface of the cover glass is at a lower position in a stacking direction than that of a top surface of the cover glass holder.

### CROSS-REFERENCE TO RELATED APPLICATION

This application claims priority under 35 U.S.C. § 119 to Japanese Patent Application No. 2025-021344 filed on Feb. 13, 2025 in the Japanese Intellectual Property Office, the disclosure of which is hereby incorporated by reference in its entirety.

### BACKGROUND

Some example embodiments of the present inventive concepts relate to semiconductor packages.

A semiconductor package used in a solid-state imaging device uses a cover glass to protect a semiconductor chip mounted on a substrate.

In general, to suppress effects (e.g., blur resulting from glass flare or heat generation from the semiconductor chip) caused by the cover glass, the cover glass is disposed spaced apart from the semiconductor chip by a certain distance in a height direction (or in a stacking direction).

For example, in a semiconductor package a resin frame extending in a columnar fashion along a height direction may be molded on an outer circumference of a substrate, and a cover glass may be fixed to the molded frame through an adhesive coated on a top surface of the frame. In addition, a cavity hermetically sealed by the substrate, the frame, and the cover glass may be disposed around a semiconductor chip.

When adopting a structure in which the cover glass is fixed through the adhesive to the frame molded on the substrate, the following problems may arise in the semiconductor package.

When a thermal load is applied to the semiconductor package having a cavity formed around the semiconductor chip during a reliability test or a solder reflow at high temperatures, outgas is generated from a resin material including the adhesive. In addition, moisture contained in air remaining in the cavity during the manufacturing process may evaporate to produce vapor. When outgas or vapor immoderately or excessively increases a cavity internal pressure, a delamination may occur in the cover glass boned to the frame.

In such semiconductor packages, because the adhesive that bonds the cover glass to the frame is disposed to directly contact the cavity, outgas generated during curing of the adhesive may remain in the cavity. For these reasons, when a thermal load is applied, the cavity internal pressure may increase even further. Therefore, in the case of the use of a structure in which the cover glass is placed on the top surface of the molded frame,, as the cavity internal pressure increases, an excessive internal pressure expansion stress directed outward from inside the cavity may facilitate delamination of the cover glass from the frame.

### SUMMARY

Some example embodiments of the present inventive concepts provide a relatively highly reliable semiconductor package capable of reducing or preventing delamination of a cover glass from a frame even under thermal load.

According to some example embodiments of the present inventive concepts, a semiconductor package includes a substrate, a semiconductor chip on a top surface of the substrate and electrically connected to the substrate, a wire connecting the substrate and the semiconductor chip, a cover glass, and a frame on the substrate and holding the cover glass, wherein the frame includes a cover glass holder holding an outer circumference of the cover glass, and the cover glass and the frame are a molded assembly in which a top surface of the cover glass is at a lower position in a stacking direction than that of a top surface of the cover glass holder.

In some example embodiments, the cover glass holder may include a bottom surface facing at least a portion of the top surface of the cover glass, and a lateral surface extending on the top surface of the cover glass and faces a lateral surface of the cover glass, wherein in the molded assembly of the cover glass and the cover glass holder, the at least the portion of the top surface of the cover glass faces the bottom surface of the cover glass holder, and the lateral surface of the cover glass faces the lateral surface of the cover glass holder.

In some example embodiments, the semiconductor package may further comprise a subsidiary adhesion part fixing a boundary to the frame. The boundary may be between a bottom surface of the cover glass and the lateral surface of the cover glass.

In some example embodiments, the cover glass holder may have a depression, the depression being between the top surface of the cover glass holder and a bottom surface of the cover glass holder, the depression being recessed toward an outer circumferential side of the frame, the bottom surface of the cover glass holder being opposite to the top surface of the cover glass holder, and in the molded assembly of the cover glass and cover glass holder, at least a portion of the outer circumference of the cover glass is accommodated in the depression.

In some example embodiments, the frame may further include a protrusion protruding in a direction opposite to the stacking direction from a bottom surface of the cover glass holder, the substrate may have an aperture into which the protrusion is inserted, the protrusion may be fixed to the substrate by an adhesion part in the aperture in a state where the protrusion is inserted into the aperture.

In some example embodiments, the protrusion may include a first segment, and a second segment lower than the first segment and on a lower side of the stacking direction, the second segment having a size in a width direction less than a size in the width direction of the first segment, the width direction being orthogonal to the stacking direction.

In some example embodiments, the protrusion may further include a hook protruding in a direction intersecting the stacking direction, and the aperture may have an insertion through which the hook is inserted along the stacking direction and a coupling with which the hook is engaged.

In some example embodiments, the substrate may include a plurality of layer members superimposed in the stacking direction and a through aperture defined through the plurality of layer members, the insertion may be a first portion of the through aperture and is defined in at least one of the plurality of layer members, and the coupling may be a second portion of the through aperture and is defined in at least another of the plurality of layer members.

In some example embodiments, when viewed from a top surface side of the cover glass, the cover glass holder may cover at least a portion of the wire.

In some example embodiments, the frame may include a frame wall supported by the substrate and extending along the stacking direction, the cover glass holder extending from a top end of the frame wall toward a central side of the substrate, and a frame connection connecting the frame wall and the cover glass holder, wherein the frame connection has a thickness greater than a thickness of the frame wall and a thickness of the cover glass holder.

In some example embodiments, the substrate may define a closed space together with the cover glass and the frame such that the semiconductor chip is accommodated in the closed space in a sealed manner.

In some example embodiments, the semiconductor package may further include a substrate wiring line in the substrate, and a ball grid array (BGA) structure comprising a solder ball, is the solder ball being electrically coupled to the substrate wiring line and is capable of mounting the substrate on a motherboard.

In some example embodiments, the semiconductor chip may be an imaging device.

According to some example embodiments of the present inventive concepts, a semiconductor package includes a substrate, a semiconductor chip on a top surface of the substrate and electrically connected to the substrate, a wire connecting the substrate and the semiconductor chip, a cover glass, and a frame on the substrate and holding the cover glass, wherein the frame includes a cover glass holder holding cover glass, the cover glass is held on a bottom surface side of the cover glass holder, the cover glass holder may include a rib that protrudes in a direction opposite to a stacking direction, and the cover glass holder holds the cover glass through an adhesion part, the adhesion part being closer than the rib to a central side of the substrate.

In some example embodiments, the frame may further include a protrusion protruding in the direction opposite to the stacking direction from a bottom surface of the cover glass holder, the substrate may have an aperture into which the protrusion is inserted, and the protrusion may be fixed to the substrate by an adhesion part in the aperture in a state where the protrusion is inserted into the aperture.

In some example embodiments, the protrusion may include a first segment, and a second segment lower than the first segment and on a lower side of the stacking direction, the second segment having a size in a width direction less than a size in the width direction of the first segment, the width direction being orthogonal to the stacking direction.

In some example embodiments, the protrusion may further comprise a hook protruding in a direction intersecting the stacking direction, and the aperture may have an insertion through which the hook is inserted along the stacking direction, a coupling with which the hook is engaged.

In some example embodiments, the substrate may include a plurality of layer members superimposed in the stacking direction and a through aperture defined through the plurality of layer members, the insertion may be a first portion of the through aperture and may be defined in in at least one of the plurality of layer members, and the coupling may be a second portion of the A through aperture and may be defined in at least another of the plurality of layer members.

In some example embodiments, when viewed from a top surface side of the cover glass, the cover glass holder may cover at least a portion of the wire.

In some example embodiments, the frame may include a frame wall supported with respect to the substrate and extending along the stacking direction, the cover glass holder extending from a top end of the frame wall toward the central side of the substrate, and a frame connection connecting the frame wall and the cover glass holder, wherein the frame connection has a thickness greater than a thickness of the frame wall and a thickness of the cover glass holder.

In some example embodiments, the substrate may define a closed space together with the cover glass and the frame such that the semiconductor chip is accommodated in the closed space in a sealed manner.

In some example embodiments, the semiconductor package may further include a substrate wiring line in the substrate, and a ball grid array (BGA) structure comprising a solder ball, is the solder ball being electrically coupled to the substrate wiring line and being capable of mounting the substrate on a motherboard.

In some example embodiments, the semiconductor chip may be an imaging device.

### BRIEF DESCRIPTION OF DRAWINGS

FIG. 1 is a simplified plan view showing a semiconductor package according to a first example embodiment.

FIG. 2 is a cross-sectional view taken along arrow line II-II depicted in FIG. 1.

FIG. 3 is an enlarged view partially showing the cross-sectional view depicted in FIG. 2.

FIG. 4 is an enlarged view partially showing the cross-sectional view depicted in FIG. 2.

FIG. 5 is a plan view showing a configuration example of an aperture provided in a substrate.

FIG. 6 is a plan view showing a configuration example of an aperture provided in a substrate.

FIG. 7 is a plan view showing a configuration example of an aperture provided in a substrate.

FIG. 8 is a cross-sectional view showing a semiconductor package according to a modification 1.

FIG. 9 is a cross-sectional view showing a semiconductor package according to a modification 2.

FIG. 10 is a cross-sectional view showing a semiconductor package according to a modification 3.

FIG. 11 is a cross-sectional view showing a semiconductor package according to a modification 4.

FIG. 12 is an enlarged view partially showing the cross-sectional view depicted in FIG. 11.

FIG. 13 is a cross-sectional view showing a semiconductor package according to a second example embodiment.

FIG. 14 is a simplified diagram showing each operation in a method of fabricating the semiconductor package according to the first example embodiment.

FIG. 15 is a simplified diagram showing each operation in a method of fabricating the semiconductor package according to the second example embodiment.

### DETAILED DESCRIPTION

It will be described in detail hereinafter some example embodiments of the present inventive concepts with reference to the accompanying drawings. In the following drawings, like numerals indicate like components, and the size of each component may be exaggerated for clarity and convenience of description. The example embodiments described below are for illustrative purpose only, and various modifications may be made therefrom.

In the following description, the expression “above” or “on” may denote not only directly on while being in contact, but indirectly on while being not in contact. Likewise, the expression “below” or “under” may denote not only directly below while being in contact, but indirectly below while being not in contact.

The singular forms are intended to include the plural forms as well, unless the context clearly indicates otherwise. Moreover, when a part is said to “comprise,” “include,” or “have”, unless explicitly stated otherwise, it does not exclude the presence of other components, but rather means that other components may also be included.

For steps for forming the methods, if an order is not clearly disclosed or if there is no disclosure opposed to the clear order, the steps may be performed in any other suitable order. The present inventive concepts are not necessarily limited to the disclosed order of the steps. The use of all examples or illustrative terms is simply to describe the present inventive concepts, and the scope of the present inventive concepts is not limited by the examples or illustrative terms unless they are limited by claims.

Furthermore, in the following description, when ordinal numbers such as “first” and “second” are used, unless specifically stated otherwise, it is used only for convenience and does not indicate any particular order.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

### First Example Embodiment

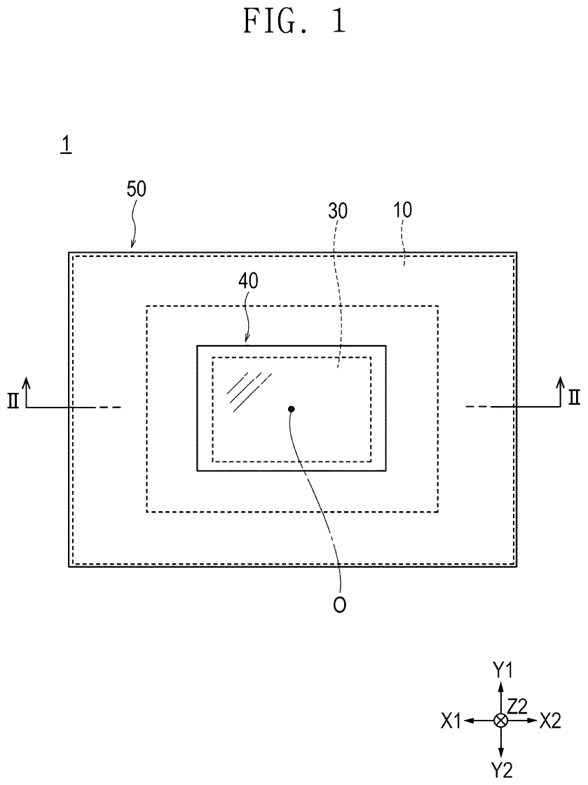

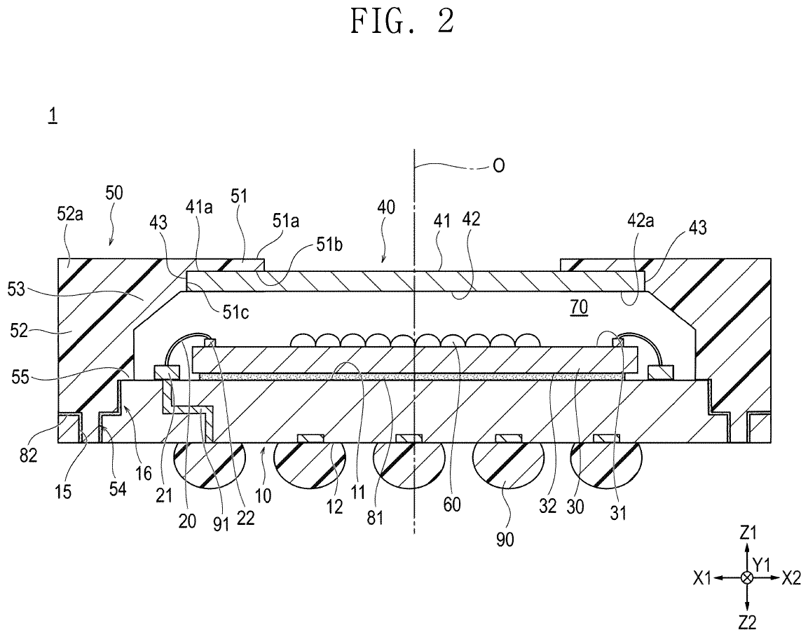

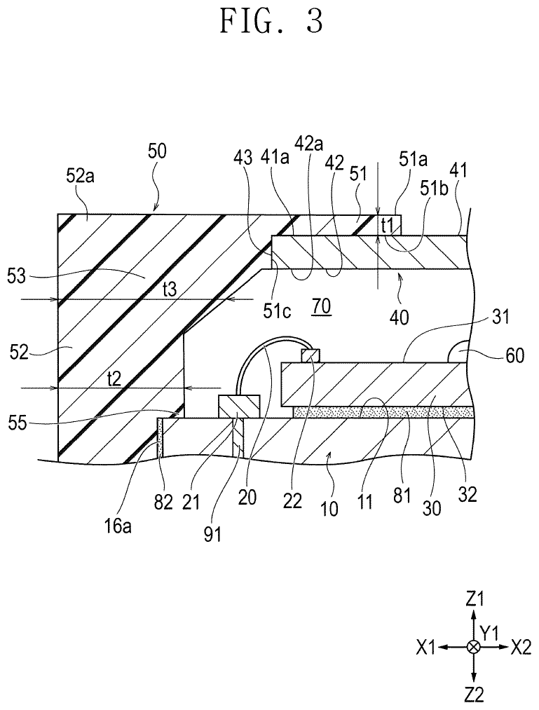

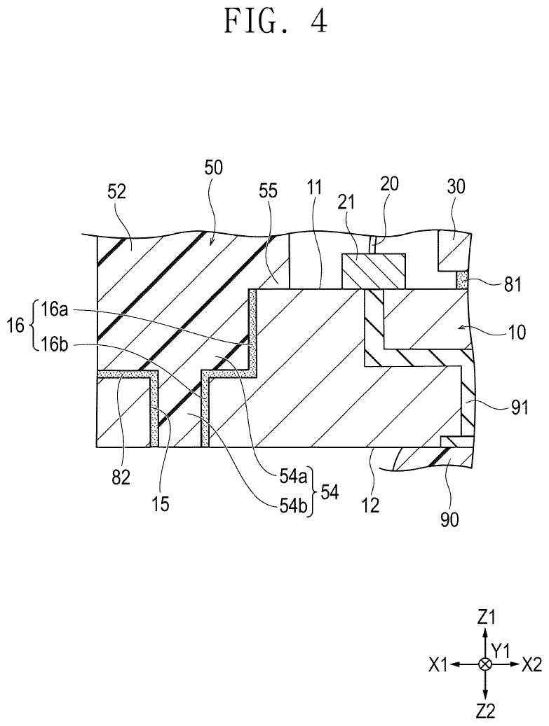

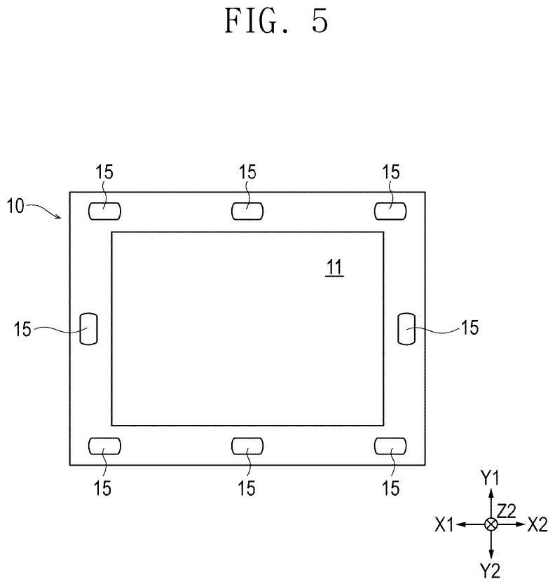

FIG. 1 is a simplified plan view showing a semiconductor package 1 according to a first example embodiment of the present inventive concepts when viewed from above a top surface side of a cover glass 40. FIG. 2 is a cross-sectional view (a stacking-directional cross-section) showing the semiconductor package 1 taken along arrow line II-II depicted in FIG. 1. FIGS. 3 and 4 are enlarged views partially showing the cross-sectional view depicted in FIG. 2. FIGS. 5 to 7 are plan views showing arrangement and shape examples of an aperture 15 formed in a substrate 10.

In this description, a direction along which a semiconductor chip 30 is stacked on the substrate 10 may be a stacking direction or a height direction (a vertical direction of FIG. 2). In each drawing, an arrow Z1 may denote an upper side (e.g., an upward direction) of the stacking direction, and an arrow Z2 may denote a lower side (e.g., a downward direction) of the stacking direction. Arrows X1-X2 may denote a width direction or a direction (a horizontal direction of FIG. 2) orthogonal to the stacking direction. In each drawing, arrows Y1-Y2 may denote a direction (a vertical direction of FIG. 1) orthogonal to each of the stacking direction and the width direction. In the description of each member, the term “top surface (top surface side)” may indicate an element positioned on the upper side of the stacking direction, and the term “bottom surface (bottom surface side)” may indicate an element positioned on the lower side of the stacking direction.

In this description, a bottom surface 12 of the substrate 10 may be disposed on an arrow Z2 side in the cross-sectional view (a stacking-directional cross-section) of FIG. 2. Further, each component will be explained in the vertical direction when a top surface 11 of the substrate 10 and a top surface 41 of the cover glass 40 are disposed on an arrow Z1 side. For example, when the vertical direction in the cross-sectional view of FIG. 2 is turned reversely, a positional relationship between a top surface and a bottom surface in each drawing is also turned reversely (the same applies below to the upper side and the lower side of the stacking direction). However, even in the case where the vertically reversed configuration is used, it does not depart from the scope of the present inventive concepts as long as a relative positional relationship is maintained between components.

As illustrated in FIGS. 1 and 2, the semiconductor package 1 may include the substrate 10 and the semiconductor chip 30 that is stacked on the top surface 11 of the substrate 10 and is electrically coupled through a wire 20 to the substrate 10.

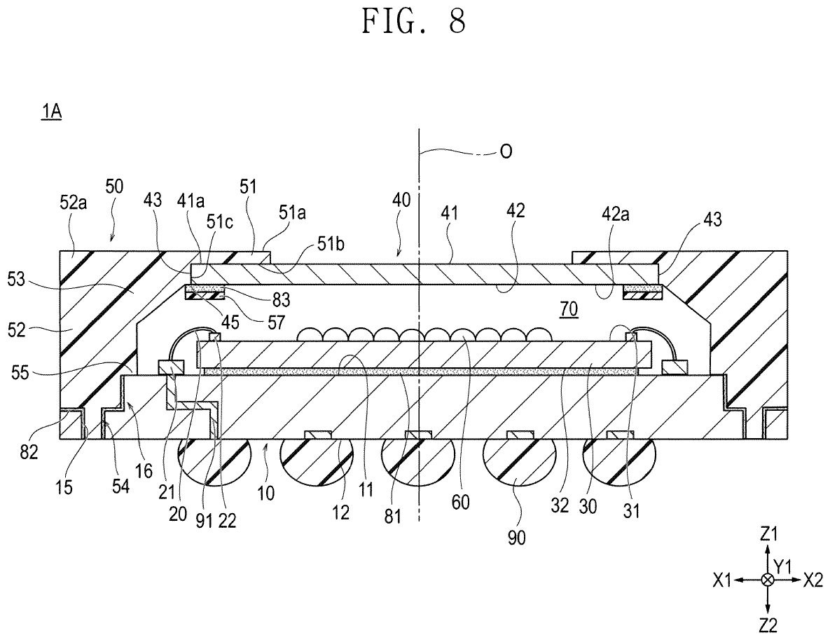

The top surface 11 (e.g., a first surface) of the substrate 10 may be a plane positioned on an arrow Z1 side in the cross-sectional view depicted in FIG. 2 (or FIGS. 8, 9, 10, 11 and 13), and the bottom surface 12 of the substrate 10 may be a plane positioned on an arrow Z2 side in the cross-sectional view depicted in FIG. 2 (or FIGS. 8, 9, 10, 11 and 13). A top surface and a bottom surface of each member may be defined in the same manner as described above.

As illustrated in FIG. 2, the semiconductor package 1 may include, for example, substrate wiring line 91 disposed in the substrate 10 and a ball grid array (BGA) structure including a solder ball 90 that is electrically coupled to the substrate wiring line 91 and is capable of mounting the substrate 10 on a motherboard (not shown).

The semiconductor package 1 may be configured to allow an incident light beam, which is incident from the top surface 41 of the cover glass 40, to pass through the cover glass 40 and to travel toward the semiconductor chip 30 mounted on the substrate 10. The semiconductor chip 30 may be an imaging device, such as a CMOS sensor or a CCD sensor. When the semiconductor chip 30 is an imaging device, optical elements, such as a microlens 60 and a color filter, may be disposed on a pixel region of the semiconductor chip 30.

As illustrated in FIG. 3, the wire 20 that electrically couples the substrate 10 and the semiconductor chip 30 may couple a first pad 21 disposed on the top surface 11 of the substrate 10 to a second pad 22 disposed on the top surface 31 of the semiconductor chip 30.

The first pad 21 may be electrically coupled through the substrate wiring line 91 formed in the substrate 10 to the solder ball 90 disposed on a certain location on the bottom surface 12 of the substrate 10.

The semiconductor chip 30 and the substrate 10 may be fixed through a die bond 81 disposed between a bottom surface 32 of the semiconductor chip 30 and the top surface 11 of the substrate 10.

The substrate 10 may be a hollow substrate in which a space around the semiconductor chip 30 is sealed by the cover glass 40 and a frame 50. In other words, the substrate 10 may form or define a space (e.g., a closed spacer) together with the cover glass 40 and a frame 50 such that the semiconductor chip 30 is accommodated in the space in a sealed manner. A cavity 70 covered by the cover glass 40 and the frame 50 may be provided around the semiconductor chip 30.

As illustrated in FIGS. 1 and 2, the semiconductor package 1 may include the cover glass 40 and the frame 50 by which the cover glass 40 is supported on the substrate 10. As illustrated in FIG. 1, the cover glass 40 may have a substantially rectangular planar shape. The cover glass 40 may be, for example, a plane-shaped glass substrate having transparency that is transparent to an incident light beam.

As illustrated in FIG. 2, the cover glass 40 may be spaced apart from the substrate 10 by a certain distance in the stacking direction. A bottom surface 42 of the cover glass 40 may be disposed to face the semiconductor chip 30.

The frame 50 may include a cover glass holder 51 that supports an outer circumference of the cover glass 40. The frame 50 may be configured to support an outer circumference 41a of the top surface 41 of the cover glass 40. The cover glass holder 51 may have a frame structure having an opening formed at a region that overlaps a region on which the semiconductor chip 30 is disposed on the substrate 10.

As illustrated in FIG. 2, the cover glass 40 and the frame 50 may be integrally molded or may be molded together to form a molded assembly to cause the top surface 41 of the cover glass 40 to be at a lower position in the stacking direction than that of a top surface 51a of the cover glass holder 51.

The phrase “at a lower position in the stacking direction” may indicate that the top surface 41 of the cover glass 40 is positioned closer than the top surface 51a of the cover glass holder 51 to the top surface 11 of the substrate 10. The language “lower position” may be defined in the same manner based on a relative positional relationship (or a closer position means a lower position) with respect to the top surface 11 of the substrate 10 even in the case where a vertical direction of the cross-sectional view of FIG. 2 is turned reversely.

In the semiconductor package 1, because the cover glass 40 and the frame 50 are integrally molded or are molded together as discussed above, an adhesive for fixing the cover glass 40 and the frame 50 may not be desired. For example, the cover glass 40 and the frame 50 may have a structure in which the cover glass 40 and the frame 50 are coupled or integrally fixed without an adhesive (or an adhesion part).

The semiconductor package 1 configured as discussed above may reduce or prevent introduction of outgas into the cavity 70 from an adhesive used to fix the cover glass 40 and the frame 50. Therefore, it may be possible to suppress an increase in cavity internal pressure that occurs when a thermal load is applied as discussed below. In addition, an adhesive may not be used for fixing the cover glass 40 and the frame 50 in an assembly process of the semiconductor package 1. Accordingly, as the cover glass 40 and the frame 50 are integrally molded or are molded together and used, it may be possible to facilitate an assembly process of the semiconductor package 1.

Because the top surface 41 of the cover glass 40 is located at a lower position in the stacking direction than that of the top surface 51a of the cover glass holder 51, the outer circumference of the cover glass 40 (e.g., the outer circumference 41a of the top surface 41 of the cover glass 40) may be covered by the cover glass holder 51. Thus, the cover glass holder 51 may press the outer circumference 41a of the top surface 41 of the cover glass 40 to maintain a pressed state from the upper side of the stacking direction.

For example, when a thermal load is applied to the semiconductor package 1 in a reliability test or a reflow process of the solder ball 90 executed under high temperatures, a cavity internal pressure may increase due to outgas generated from the frame 50, the substrate 10, and the die bond 81 or due to vapor produced from the evaporation of moisture contained in air present within the cavity 70. As discussed above, the semiconductor package 1 may have a structure in which the outer circumference 41a of the cover glass 40 is pressed from the upper side of the stacking direction by the cover glass holder 51. Thus, even when an internal pressure expansion stress directed outward from inside the cavity 70 is generated due to an increase in cavity internal pressure and thus the cover glass 40 is subjected to the internal pressure expansion stress, the cover glass holder 51 may effectively reduce or prevent the cover glass 40 from being delaminated or detached from the frame 50.

As illustrated in FIGS. 2 and 3, the cover glass holder 51 may have a bottom surface 51b disposed to face at least a portion of the top surface 41 of the cover glass 40 and a lateral surface 51c disposed to face a lateral surface 43 connected to the top surface 41 of the cover glass 40.

As illustrated in FIGS. 2 and 3, the cover glass 40 and the cover glass holder 51 may be integrally molded or may be molded together to cause at least a portion (a portion including the outer circumference 41a of the top surface 41) of the top surface 41 of the cover glass 40 to face the bottom surface 51b of the cover glass holder 51 and to cause the lateral surface 43 of the cover glass 40 to face the lateral surface 51c of the cover glass holder 51.

As discussed above, because the semiconductor package 1 is configured such that the cover glass 40 and the cover glass holder 51 are integrally molded or are molded together to cause the top surface 41 of the cover glass 40 to face the bottom surface 51b of the cover glass holder 51 and to cause the lateral surface 43 of the cover glass 40 to face the lateral surface 51c of the cover glass holder 51, the cover glass 40 and the cover glass holder 51 may be fixed in a closely adhered state at two surfaces (the bottom surface 51b and the lateral surface 51c) of the cover glass holder 51. Therefore, there may be a further improvement in adhesion strength between the cover glass 40 and the cover glass holder 51 in the semiconductor package 1.

As illustrated in FIGS. 2 and 4, the frame 50 may include a protrusion 54, which is located below the cover glass holder 51, on the lower side of the stacking direction, and the protrusion 54 may protrude in a direction opposite to the stacking direction. The expression “the lower side of the stacking direction” may indicate a bottom surface side of the semiconductor package 1 (or a bottom surface side of the substrate 10) in the cross-sectional view depicted in FIG. 2.

The protrusion 54 may protrude downward in the stacking direction to a position below the top surface 11 of the substrate 10. The substrate 10 may have an aperture 15 into which the protrusion 54 is inserted. The aperture 15 may be formed in the vicinity of an outer circumference of the substrate 10, and the outer circumference of the substrate 10 may face the protrusion 54. The aperture 15 may be formed to penetrate between the top surface 11 and the bottom surface 12 of the substrate 10. No particular limitation is limited on the detailed shape, arrangement, or the number of the aperture 15, and for example, the aperture 15 may have any other suitable shapes depicted in FIGS. 5 to 7. FIGS. 5 to 7 are simplified plan views showing the substrate 10 when viewed from the upper side of the stacking direction.

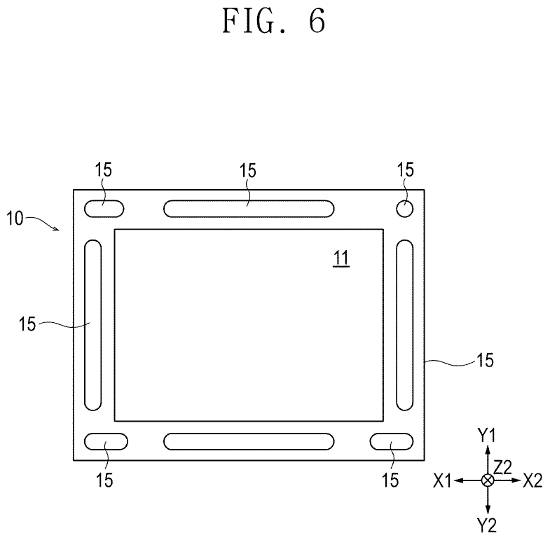

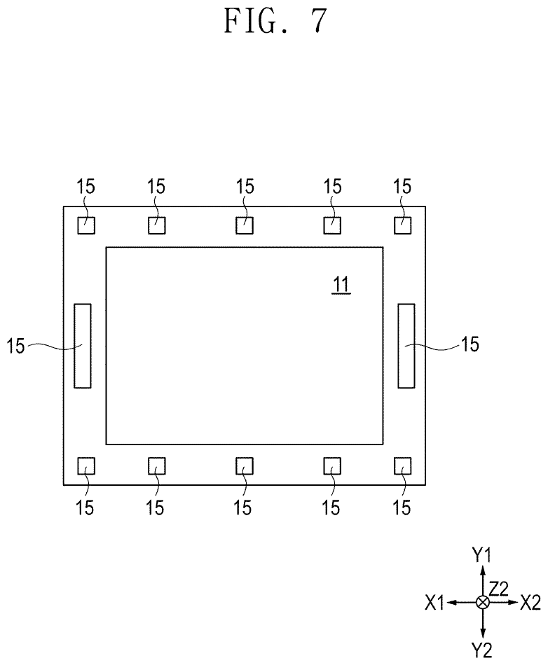

As illustrated in FIG. 5, the apertures 15 may be oblong holes that are disposed at a constant interval along the outer circumference of the substrate 10. In FIG. 5, all of the apertures 15 are configured in the same shape. As illustrated in FIG. 6, the apertures 15 may be substantially circular or oblong holes having different sizes formed along the outer circumference of the substrate 10. As illustrated in FIG. 7, the apertures 15 may have square or rectangular planar shapes.

As illustrated in FIGS. 2 and 3, in a state where the protrusion 54 is inserted into the aperture 15, the protrusion 54 may be fixed to the substrate 10 through an adhesion part 82 disposed in the aperture 15 in a state where the protrusion 54 is inserted into the aperture 15 such that the frame 50 and the substrate 10 may be fixed through the adhesion part 82 disposed in the aperture 15. The adhesion part 82 may be formed from, for example, an adhesive filled in the aperture 15. Because the protrusion 54 and the aperture 15 extend along the stacking direction, adhesion strength between the protrusion 54 and the aperture 15 may be improved due to an anchor effect. Therefore, even when the cavity internal pressure is increased, it may be possible to more effectively reduce or prevent delamination between the frame 50 and the substrate 10.

As illustrated in FIG. 4, the protrusion 54 may include a first segment 54a and a second segment 54b which is disposed, lower than the first segment 54a, on the lower side of the stacking direction and whose size in the width direction orthogonal to the stacking direction is less than that of the first segment 54a. The aperture 15 may have a step difference 16 formed in a cross-sectional shape that correspond to that of the first and second segments 54a and 54b of the protrusion 54. The step difference 16 may include a first segment 16a formed on the upper side of the stacking direction of the aperture 15 and a second segment 16b which is disposed lower than (or under) the first segment 16a, on the lower side of the stacking direction. The size of the second segment 16b in the width direction orthogonal to the stacking direction is less than that of the first segment 16a.

As illustrated in FIG. 4, in a state where the protrusion 54 is inserted into the aperture 15, the first segment 54a of the protrusion 54 may be disposed on the first segment 16a of the step difference 16, and the second segment 54b of the protrusion 54 may be disposed on the second segment 16b of the step difference 16.

As discussed above, at the step difference 16 of the substrate 10, the frame 50 may be fixed through the first segment 16a and the second segment 16b whose size in the width direction is less than that of the first segment 16a. Because the protrusion 54, which is positioned at a lower portion of the frame 50, is used to fix the frame 50 through the adhesion part 82 to the substrate 10, when a frame wall 52 is subjected to the internal pressure expansion stress directed outward from inside the cavity 70 accompanied by an increase in cavity internal pressure of the semiconductor package 1, an anchor effect may be increased due to stress that acts toward a central side (a right side of the first segment 16a or the second segment 16b depicted in FIG. 4) of the substrate 10 against the protrusion 54. Thus, it may be possible to disperse stress that tends to pull the frame 50 upward and thus to more effectively reduce or prevent delamination between the frame 50 and the substrate 10.

As illustrated in FIGS. 3 and 4, an inner circumference 55 (an inner circumference positioned in the vicinity of a bottom end of the frame wall 52) of the frame 50 may be disposed on, for example, the outer circumference (a portion positioned at an outer circumferential side farther away than the first pad 21) of the top surface 11 of the substrate 10. Such placement of the frame 50 may allow the inner circumference 55 to intervene between the cavity 70 and the adhesion part 82 that is disposed in the aperture 15, and thus the adhesion part 82 may be reduced or prevented from being in direct contact with (e.g., from being in fluidic communication with) the cavity 70. Therefore, the cavity 70 may be reduced or prevented from introduction of outgas generated during curing of an adhesive used for forming the adhesion part 82.

When the semiconductor package 1 is assembled, the inner circumference 55 of the frame 50 may be disposed to be placed against the outer circumference of the top surface 11 of the substrate 10, and therefore the frame 50 may be easily disposed on the substrate 10. Accordingly, it may be possible to simplify a fabrication process of the semiconductor package 1.

To increase adhesion strength between the frame 50 and the substrate 10, an adhesion part may be placed between the inner circumference 55 of the frame 50 and the outer circumference of the top surface 11 of the substrate 10. However, when an adhesion part is placed on the location mentioned above, the adhesion part may be directly adjacent to the cavity 70 and thus may increase the likelihood of an increase in outgas generation amount within the cavity 70. FIG. 4 depicts an example in which no adhesion part is disposed between the inner circumference 55 of the frame 50 and the outer circumference of the top surface 11 of the substrate 10 and thus there may be a further suppression of an increase in outgas generation amount within the cavity 70. A balance between adhesion strength and outgas generation may be changed depending on adhesion areas and/or types of adhesion part, and therefore the adhesion part may be placed on an appropriate location while maintaining the balance between adhesion strength and outgas generation.

When viewed from a top surface side of the cover glass 40 (the planar view of FIG. 1), the cover glass holder 51 may be disposed to cover at least a portion of the wire 20. For example, referring to FIGS. 2 and 3, the wire 20 may be disposed to allow an end portion thereof that is coupled to the second pad 22 to overlap the cover glass holder 51 in the vertical direction.

Because, as discussed above, the wire 20 is disposed to be covered by the cover glass holder 51, it may be possible to reduce or prevent a reflected light flare caused by incidence of an incident light beam on the wire 20 when the incident light beam is incident on the semiconductor chip 30. Accordingly, noise may be reduced or prevented from being introduced into electrical signals produced from the semiconductor chip 30.

As illustrated in FIGS. 2 and 3, the frame 50 may include the frame wall 52 that is supported by the substrate 10 and extends along the stacking direction, the cover glass holder 51 that extends from a top end 52a of the frame wall 52 toward a central flange side of the substrate 10, and a frame connection 53 that connects the frame wall 52 and the cover glass holder 51.

A center O of the substrate 10 may be a center in a plane direction on the planar view depicted in FIG. 1. For example, the center O of the substrate 10 may indicate a position of an intersection at which a center of the width direction (arrows X1-X2 direction) depicted in FIG. 1 intersects a center of a direction (arrows Y1-Y2 direction) orthogonal to the width direction.

The frame wall 52 may extend substantially vertically along the stacking direction. The frame wall 52 may be provided on its bottom end with the protrusion 54 that protrudes toward a downward direction.

As illustrated in FIG. 3, the frame connection 53 may have a thickness greater than that of the frame wall 52 and that of the cover glass holder 51. For example, a third thickness t3 of the frame connection 53 depicted in FIG. 3 may be greater than a second thickness t2 of the frame wall 52 and a first thickness t1 of the cover glass holder 51. In addition, as illustrated in FIG. 3, the first thickness t1 may be a thickness of the cover glass holder 51 (a linear distance between the top surface 51a and the bottom surface 51b of the cover glass holder 51) in the stacking direction, the second thickness t2 may be a thickness of the frame wall 52 (a linear distance between outer and inner sidewalls of the frame wall 52) in a direction orthogonal to the stacking direction at an arbitrary point in the stacking direction, and the third thickness t3 may be a thickness of the frame connection 53 (a linear distance between outer and inner sidewalls of the frame connection 53) in a direction orthogonal to the stacking direction at an arbitrary point in the stacking direction.

As discussed above, the semiconductor package 1 may be formed such that the third thickness t3 of the frame connection 53 is greater than those of other components 51 and 52 of the frame 50. Therefore, as illustrated in FIG. 3, a boundary between the frame wall 52 and the cover glass holder 51 may be formed thick, and the frame 50 may have a chamfered cross-section at a portion of an inside thereof. Thus, there may be a reduction in sectional area of the cavity 70 at a region that corresponds to a portion where the frame connection 53 is formed.

As discussed above, as the cavity 70 is formed to have a reduced sectional area at a region that corresponds to a portion where the frame connection 53 is formed, the cavity 70 may have a reduced volume. Thus, there may be a reduction in volume of air or outgas present within the cavity 70. Accordingly, even when the semiconductor package 1 is provided with a thermal load and the cavity internal pressure increased, increase in cavity internal pressure may be reduced. Moreover, as there may be a reduction in volume of air or outgas present within the cavity 70, the bottom surface 42 of the cover glass 40 may be reduced or prevented from blur occurring when a thermal load is applied. Hence, the cover glass 40 may be suppressed from a reduction in transmittance.

Each component of the semiconductor package 1 may be formed of, for example, the following material. The following material, however, is merely examples, and no limitation is imposed thereon.

The substrate 10 may be formed of, for example, polyimide, polyester, ceramic, epoxy, bismaleimidetriazine, phenolic resin, alumina, aluminum nitride, beryllium oxide, ceramic such as silicon nitride, or glass material (quartz glass, borosilicate glass, and alkali-free glass).

The wire 20 may be formed of a metallic material (e.g., copper, silver, or gold). The substrate wiring line 91 in the substrate 10 may be formed of a material similar to that of the wire 20.

The semiconductor chip 30 may be formed of, for example, silicon.

The cover glass 40 may be, for example, quartz glass, borosilicate glass, or alkali-free glass.

The frame 50 may be formed of, for example, a thermosetting resin. In addition, an injection molding may be employed to use a certain mold to integrally mold or mold together the frame 50 and the cover glass 40.

The die bond 81 and the adhesion part 82 may be formed of or include, for example, an adhesive made of an epoxy-based resin material. This may hold true for a first subsidiary adhesion part 83 and a second subsidiary adhesion part 84 which will be discussed below. However, a detailed material of the adhesive in use is not particularly limited, and for example, an acryl-based resin material, a silicon-based resin material, or silver-added paste-like material may be used as a material of the adhesive.

As discussed above, the semiconductor package 1 according to the present example embodiment may include the substrate 10 and the semiconductor chip 30 that is stacked on the top surface 11 of the substrate 10 and is electrically coupled through the wire 20 to the substrate 10. The semiconductor package 1 may further include the cover glass 40 and the frame 50 by which the cover glass 40 is held on the substrate 10. The frame 50 may include the cover glass holder 51 that holds the outer circumference of the cover glass 40. The cover glass 40 and the frame 50 may be integrally molded or may be molded together in a state where the top surface 41 of the cover glass 40 is disposed at a lower position in the stacking direction than that of the top surface 51a of the cover glass holder 51.

The semiconductor package 1 configured as discussed above may reduce or prevent introduction of outgas into the cavity 70 from an adhesive used to fix the cover glass 40 and the frame 50. As the top surface 41 of the cover glass 40 is disposed at a lower position in the stacking direction than that of the top surface 51a of the cover glass holder 51, the outer circumference of the cover glass 40 may be pressed from the upper side of the stacking direction by the cover glass holder 51. Thus, an internal pressure expansion stress directed outward from inside the cavity 70 may be generated due to an increase in cavity internal pressure. Even when the cover glass 40 is subjected to the internal pressure expansion stress, the cover glass holder 51 may effectively reduce or prevent the cover glass 40 from being delaminated or detached from the frame 50. Accordingly, the semiconductor package 1 may have an improve adhesion strength, thereby reducing or preventing the cover glass 40 from being delaminated from the frame 50 even when a thermal load is applied.

The following will explain modifications of the first example embodiment discussed above. In description of the modifications, omission will be made to avoid a repetitive explanation of those discussed in the first example embodiment. In addition, components or elements that exhibit the same functions and effects are allocated the same reference numerals, and explanations thereof will be omitted.

### Modification 1

FIG. 8 is a cross-sectional view showing a semiconductor package 1A according to a modification 1. As illustrated in FIG. 8, the semiconductor package 1A may further include a first subsidiary adhesion part 83 by which a boundary 45 between the bottom surface 42 of the cover glass 40 and the lateral surface 43 of the cover glass 40 is fixed to the frame 50.

In the semiconductor package 1A, the first subsidiary adhesion part 83, which is disposed on the cover glass 40 and the frame 50 to run across the boundary 45, may cause that the cover glass 40 is fixed to the frame 50 at the bottom surface 42 of the cover glass 40. Thus, there may be a further improvement in adhesion strength of the cover glass 40 to the frame 50.

In addition, in the semiconductor package 1A, a frame-shaped plate 57 having an opening may be fixed through the first subsidiary adhesion part 83 to the frame 50. The plate 57 may be fixed to the cover glass 40 and the frame 50 through the first subsidiary adhesion part 83 by which the plate 57 overlaps the boundary 45. Thus, a bonding force between the frame 50 and the cover glass 40 may be reinforced to more effectively increase adhesion strength in the vicinity of the cover glass holder 51.

The plate 57 may be formed of, for example, a resin material or a metallic material.

### Modification 2

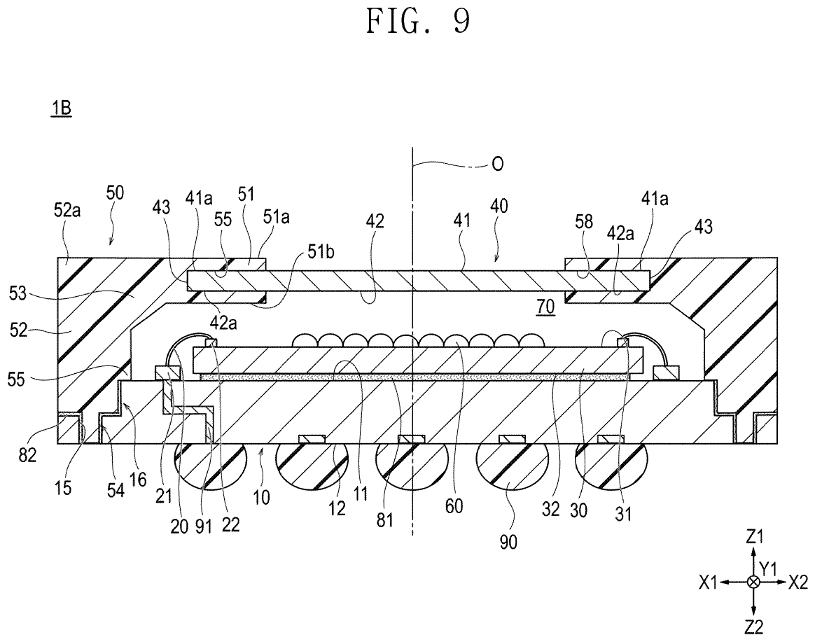

FIG. 9 is a cross-sectional view showing a semiconductor package 1B according to a modification 2. As illustrated in FIG. 9, the cover glass holder 51 may further include a depression 58 that is formed between the top surface 51a and the bottom surface 51b of the cover glass holder 51 and is recessed toward an outer circumferential side of the frame 50.

The cover glass 40 may be integrally molded or may be molded with the cover glass holder 51 in a state where the depression 58 receives at least a portion of the outer circumference of the cover glass 40 (e.g., at least a portion of the outer circumference 41a of the top surface 41). The depression 58 may accommodate the lateral surface 43 of the cover glass 40, the outer circumference 42a of the bottom surface 42, and the outer circumference 41a of the top surface 41.

In the semiconductor package 1B, as discussed above, at least a portion of the outer circumference of the cover glass 40 may be inserted into the depression 58 formed in the cover glass holder 51. Therefore, adhesion strength may be improved due to an increase in adherence between the cover glass holder 51 and the cover glass 40.

### Modification 3

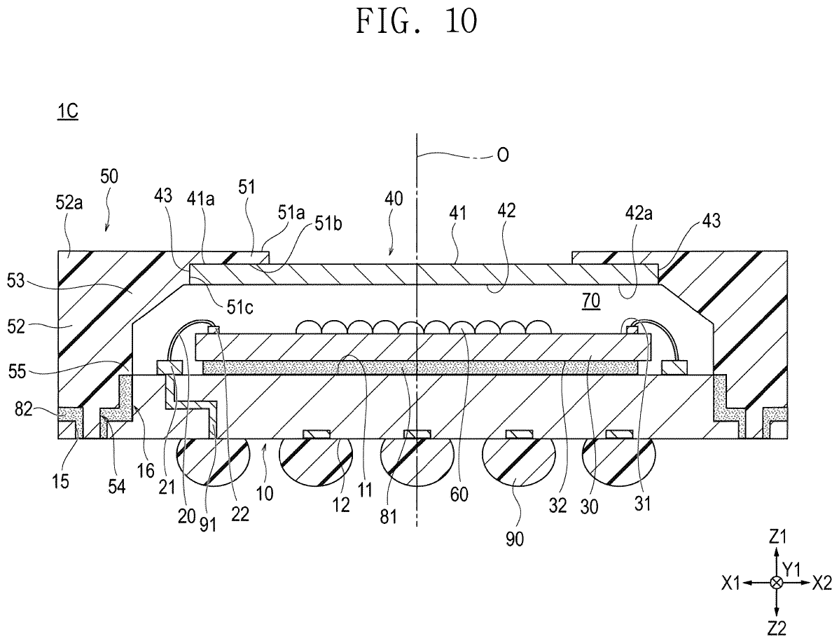

FIG. 10 is a cross-sectional view showing a semiconductor package 1C according to a modification 3. In the semiconductor package 1 according to the first example embodiment discussed above, the inner circumference 55 of the frame 50 may be disposed to contact the outer circumference of the top surface 11 of the substrate 10. In contrast, in the semiconductor package 1C according to a modification 3, the inner circumference 55 of the frame 50 may be disposed farther outward than the outer circumference of the top surface 11 of the substrate 10. Such placement of the inner circumference 55 of the frame 50 may increase a sectional area of the aperture 15, and thus a greater number of the adhesion parts 82 may be provided in the aperture 15. Accordingly, there may be a further improvement in adhesion strength between the frame 50 and the substrate 10.

### Modification 4

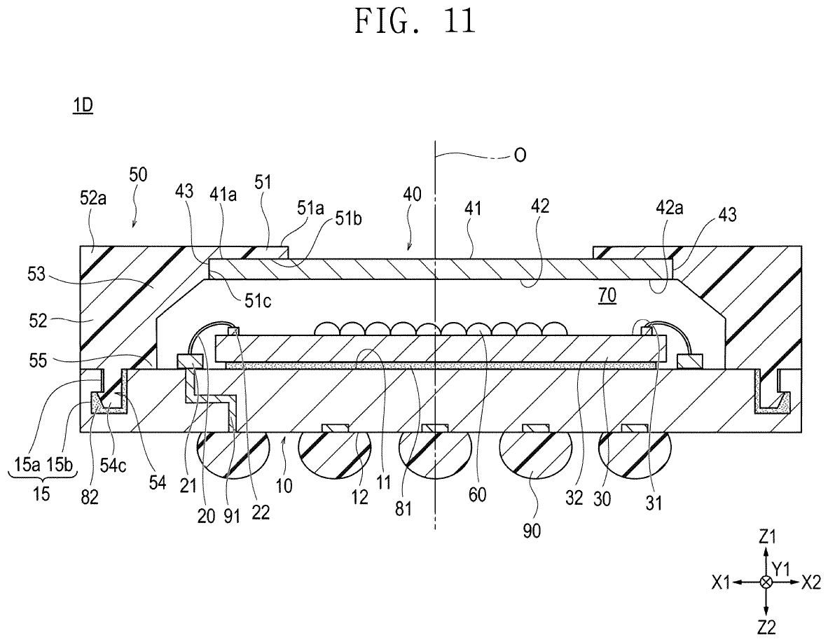

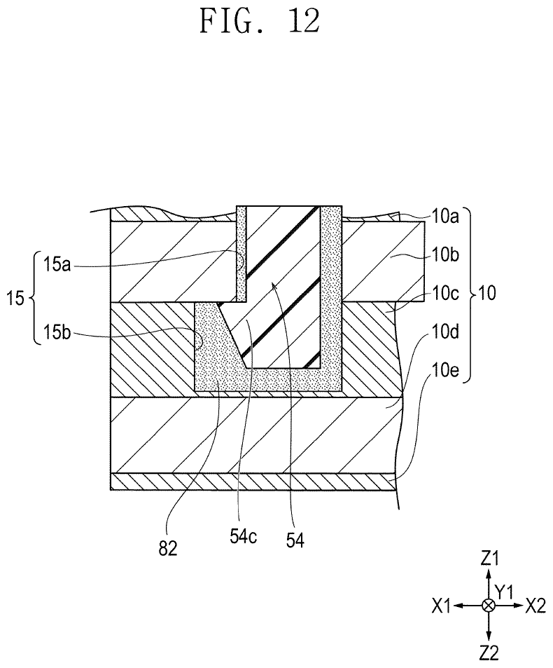

FIGS. 11 and 12 are cross-sectional views showing a semiconductor package 1D according to a modification 4. In the semiconductor package 1D according to a modification 4, a structure of the protrusion 54 of the frame 50 and a structure of the aperture 15 of the substrate 10 may be different from those of the first example embodiment discussed above.

As illustrated in FIGS. 11 and 12, the protrusion 54 may have a hook 54c that protrudes in a direction that intersects the stacking direction. The hook 54c may be formed at a bottom end of the protrusion 54. The hook 54c may have a return structure capable of being engaged with a coupling 15b which will be discussed below.

The aperture 15 may have an insertion 15a through which the hook 54c is inserted along the stacking direction and a coupling 15b with which the hook 54c is engaged. The aperture 15 may be formed to reach an intermediate position in a thickness direction of the substrate 10 so as not to completely penetrate in the thickness direction through the substrate 10. The insertion 15a may extend along the stacking direction to have a substantially constant sectional area (an area when viewed on an X-Y plane) along the thickness direction of the substrate 10. The coupling 15b may be formed at a bottom end of the insertion 15a (a bottom end of the aperture 15). The coupling 15b may have a sectional area (an area when viewed on an X-Y plane) greater than that of the insertion 15a. In some example embodiments, as illustrated in FIG. 11, the coupling 15b may have a diameter greater than that of the insertion 15a.

As illustrated in FIG. 12, according to the present modification, when the protrusion 54 is inserted into the aperture 15, the hook 54c of the protrusion 54 may be engaged with the coupling 15b. In this state, the adhesion part 82 provided in the aperture 15 may fix the frame 50 and the substrate 10. Thus, in the semiconductor package 1D, adhesion strength between the frame 50 and the substrate 10 may be physically increased through the coupling 15b and the hook 54c. Therefore, it may be possible to more effectively reduce or prevent delamination between the frame 50 and the substrate 10.

As illustrated in FIG. 12, the substrate 10 of the semiconductor package 1D may include first, second, third, fourth, and fifth layer members 10a, 10b, 10c, 10d, and 10e that are superimposed in the stacking direction, and a through aperture defined therethrough.

A first portion of the through aperture that constitutes or defines the insertion 15a may be formed or defined in at least one of the plurality of layers members 10a, 10b, 10c, 10d, and 10e. In addition, a second portion of the through aperture that constitutes or defines the coupling 15b may be formed or defined in at least another of the plurality of layer members 10a, 10b, 10c, 10d, and 10e.

According to the present modification, a first portion of the through aperture that constitutes or defines the insertion 15a may be formed or defined in the first and second layer members 10a and 10b disposed on the upper side of the stacking direction. In addition, the second portion of the through aperture that constitutes of defines the coupling 15b may be formed in the third layer member 10c disposed on an intermediate point of the stacking direction. No through aperture may be formed in the fourth and fifth layer members 10d and 10e disposed on the lower side of the stacking direction.

In the semiconductor package 1D, the substrate 10 may be manufactured by forming a through aperture having a certain cross-section (sectional area) in each of the first, second, and third layer members 10a, 10b, and 10c, and then stacking the fourth and fifth layer members 10d and 10e. Thus, the substrate 10 may be easily obtained which includes the insertion 15a and the coupling 15b whose cross-sections (sectional areas) are different from each other.

When the substrate 10 consists of five layer members 10a, 10b, 10c, 10d, and 10e, for example, the first and fifth layer members 10a and 10e may be formed of a solder resist, the second and fourth layer members 10b and 10d may be formed of a prepreg, and the third layer member 10c may be formed of a core material.

No particular limitation is imposed on the number, thickness, or material of the layer members 10a, 10b, 10c, 10d, and 10e, nor on which layer member a through aperture is to be formed.

The following will describe a second example embodiment of the present inventive concepts. In description of the second example embodiment, omission will be made to avoid a repetitive explanation of those discussed in the first example embodiment and the aforementioned modifications. In addition, components or elements that exhibit the same functions and effects are allocated the same reference numerals, and explanations thereof will be omitted.

### Second Example Embodiment

The semiconductor package 1 according to the first example embodiment may have a structure in which the cover glass 40 is integrally molded or is molded with the frame 50 in a state where the cover glass 40 is disposed on the cover glass holder 51. In a semiconductor package 1E according to the second example embodiment, the cover glass 40 is not integrally molded or is not molded with the frame 50. The following description will focus on the semiconductor package 1E.

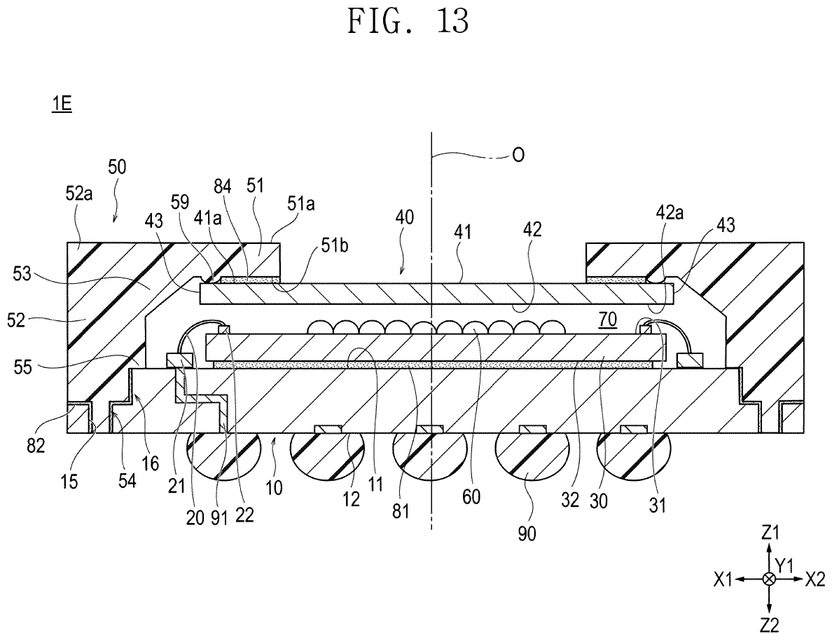

As illustrated in FIG. 13, the semiconductor package 1E may include a substrate 10, a semiconductor chip 30 that is stacked on a top surface 11 of the substrate 10 and is electrically coupled through a wire 20 to the substrate 10, a cover glass 40, and a frame 50 by which the cover glass 40 is held on the substrate 10.

The frame 50 may include a cover glass holder 51 that holds the cover glass 40. The cover glass 40 may be held on a bottom surface side of the cover glass holder 51. The cover glass holder 51 may have a rib 59 that protrudes toward the lower side of the stacking direction. The cover glass holder 51 may hold the cover glass 40 through a second subsidiary adhesion part 84 provided closer than the rib 59 to a central side of the substrate 10.

The rib 59 may be configured to have, for example, an arc sectional shape that protrudes toward the lower side of the stacking direction. However, no particular limitation is imposed on the sectional shape or size of the rib 59.

The cover glass 40 of the semiconductor package 1E may be held on the bottom surface side of the cover glass holder 51. Thus, an outer circumference (e.g., an outer circumference 41a of the top surface 41) of the cover glass 40 may be covered by the cover glass holder 51. For example, the outer circumference of the cover glass 40 may be held in a state of being covered from the upper side of the stacking direction by the cover glass holder 51. Therefore, likewise the semiconductor package 1 according to the first example embodiment, in the semiconductor package 1E, even when an internal pressure expansion stress directed outward from inside a cavity 70 is generated accompanied by or due to an increase in cavity internal pressure and thus the cover glass 40 is subjected to the internal pressure expansion stress, the cover glass holder 51 may effectively reduce or prevent the cover glass 40 from delamination or detachment from the frame 50.

In the semiconductor package 1E, the second subsidiary adhesion part 84, which holds the cover glass 40 on the cover glass holder 51, may be formed closer than the rib 59 to the central side of the substrate 10. As the adhesion part 84 is disposed as discussed above, the adhesion part 82 may be reduced or prevented from being exposed within or to the cavity 70. Thus, when outgas is generated from the adhesion part 84, the outgas may be outwardly discharged from the cavity 70. Therefore, even when a cavity internal pressure is increased due to a thermal load applied to the semiconductor package 1E, there may be a reduction in increase in cavity internal pressure. Accordingly, it may be possible to effectively reduce or prevent delamination or detachment of the cover glass 40 from the frame 50.

In addition, although not described, as long as the aforementioned effect can be exerted, the semiconductor package 1E according to the second example embodiment may arbitrarily and selectively adopt the same structure (e.g., a structure of the frame connection 53, a structure of the aperture 15, and/or a structure of the hook 54c) as that explained in the semiconductor package 1 according to the first example embodiment.

### Method of Fabricating the Semiconductor Package 1

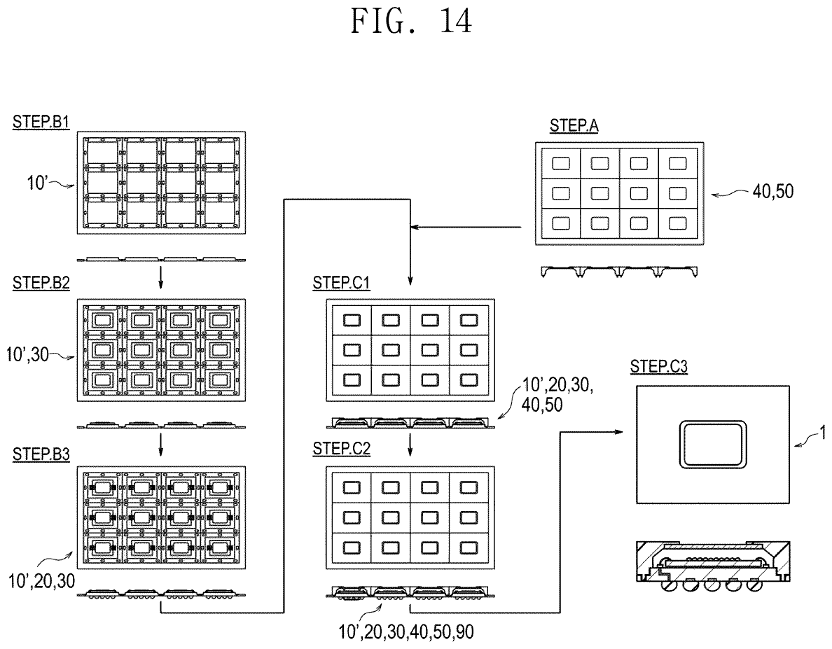

FIG. 14 is a simplified diagram showing each operation in a method of fabricating the semiconductor package 1 according to the first example embodiment.

A cover glass 40 and a frame 50 that are integrally molded or are molded together may be prepared (OPERATION A). For example, it may be possible to use a cover glass 40 and a frame 50 that are integrally molded or are molded together from an outsource provider. In this case, it may not be desired to manufacture and store a mold for integrally molding the cover glass 40 and the frame 50 or molding the cover glass 40 and the frame 50 together. Accordingly, it may be possible to reduce cost and/or work load for manufacturing and storing the mold.

A series of steps may be sequentially performed in such a way that a substrate 10′ (a substrate before being cut into individual pieces) is prepared (OPERATION B1), a semiconductor chip 30 is mounted on the substrate 10′ (OPERATION B2), and then the substrate 10′ and the semiconductor chip 30 are coupled through a wire 20 (OPERATION B3).

The cover glass 40 and the frame 50 that are integrally molded or are molded together may be attached to the substrate 10′ on which the wire 20 and the semiconductor chip 30 are mounted (OPERATION C1).

A solder ball 90 may be attached to the substrate 10′ (OPERATION C2). The substrate 10′ to which constituent members 20, 30, 40, 50, and 90 are attached may be cut into individual pieces to fabricate the semiconductor package 1 (OPERATION C3).

### Method of Fabricating the Semiconductor Package 1E

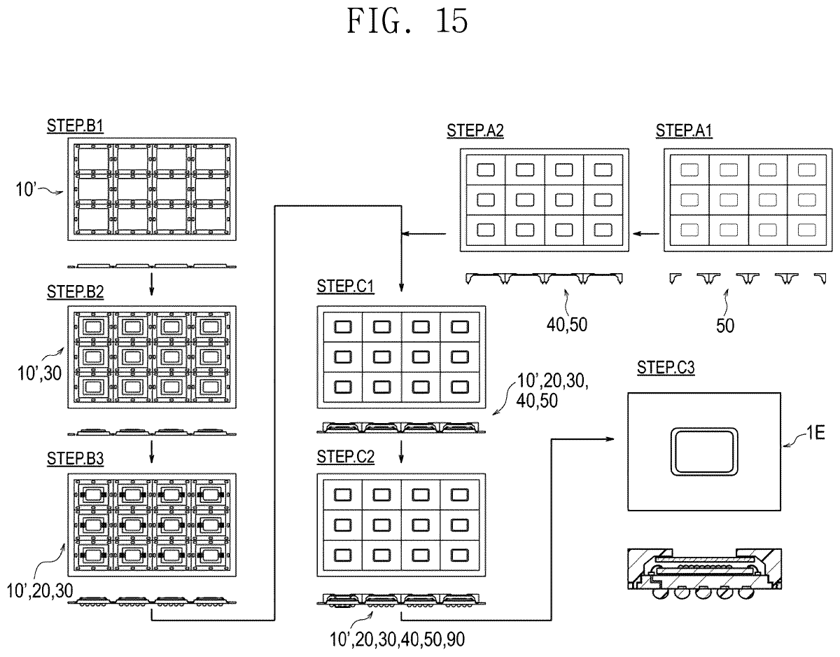

FIG. 15 is a simplified diagram showing each operation in a method of fabricating the semiconductor package 1E according to the second example embodiment.

A cover glass 40 and a frame 50 may be prepared (OPERATION A). An adhesion part 84 may be used to fix the cover glass 40 to the frame 50.

A series of steps may be sequentially performed in such a way that a substrate 10′ (a substrate before being cut into individual pieces) is prepared (OPERATION B1), a semiconductor chip 30 is mounted on the substrate 10′ (OPERATION B2), and then the substrate 10′ and the semiconductor chip 30 are coupled through a wire 20 (OPERATION B3).

The cover glass 40 and the frame 50 may be attached to the substrate 10′ on which the wire 20 and the semiconductor chip 30 are mounted (OPERATION C1).

A solder ball 90 may be attached to the substrate 10′ (OPERATION C2). The substrate 10′ to which constituent members 20, 30, 40, 50, and 90 are attached may be diced to fabricate the semiconductor package 1E (OPERATION C3).

According to an example embodiment of the present inventive concepts, a relatively highly reliable semiconductor package may be obtained which is capable of reducing or preventing delamination of a cover glass from a frame even under thermal load.

According to an example embodiment of the present inventive concepts, a method of manufacturing a semiconductor package includes preparing a cover glass and a frame that are jointly molded with each other to form a molded assembly, preparing a substrate, and mounting a semiconductor chip on the substrate, coupling the substrate and the semiconductor chip with each other through a wire, attaching the molded assembly to the substrate on an upper surface of which the wire and the semiconductor chip are mounted, and attaching a solder ball to a lower surface of the substrate, and cutting the substrate into individual pieces to fabricate the semiconductor package.

In some example embodiments, the preparing the cover glass and the frame may include fixing the cover glass to the frame using an adhesion part.

Although semiconductor packages according to the present inventive concepts have been described through a plurality of example embodiments and a plurality of modifications, the present inventive concepts are not limited to the description provided in the specification and may be appropriately changed.

For example, a ball grid array (BGA) structure is illustrated in this specification as a structural example of the semiconductor package, but the present inventive concepts are not limited thereto.

1. A semiconductor package, comprising:
a substrate;
a semiconductor chip on a top surface of the substrate and electrically connected to the substrate;
a wire connecting the substrate and the semiconductor chip;
a cover glass; and
a frame on the substrate and holding the cover glass on the substrate,
wherein the frame comprises a cover glass holder holding an outer circumference of the cover glass, and
wherein the cover glass and the frame are a molded assembly in which a top surface of the cover glass is at a lower position in a stacking direction than that of a top surface of the cover glass holder.

2. The semiconductor package of claim 1, wherein the cover glass holder comprises:
a bottom surface facing at least a portion of the top surface of the cover glass; and
a lateral surface extending on the top surface of the cover glass and facing a lateral surface of the cover glass,
wherein in the molded assembly of the cover glass and the cover glass holder, the at least the portion of the top surface of the cover glass faces the bottom surface of the cover glass holder, and the lateral surface of the cover glass faces the lateral surface of the cover glass holder.

3. The semiconductor package of claim 2, further comprising:
a subsidiary adhesion part fixing a boundary to the frame, the boundary being between a bottom surface of the cover glass and the lateral surface of the cover glass.

4. The semiconductor package of claim 1, wherein
the cover glass holder has a depression, the depression being between the top surface of the cover glass holder and a bottom surface of the cover glass holder, the depression being recessed toward an outer circumferential side of the frame, the bottom surface of the cover glass holder being opposite to the top surface of the cover glass holder, and
in the molded assembly of the cover glass and the cover glass holder, at least a portion of the outer circumference of the cover glass is accommodated in the depression.

5. The semiconductor package of claim 1, wherein
the frame further comprises a protrusion protruding in a direction opposite to the stacking direction from a bottom surface of the cover glass holder,
the substrate has an aperture into which the protrusion is inserted, and
the protrusion is fixed to the substrate by an adhesion part in the aperture in a state where the protrusion is inserted into the aperture.

6. The semiconductor package of claim 5, wherein the protrusion comprises:
a first segment; and
a second segment lower than the first segment and on a lower side of the stacking direction, the second segment having a size in a width direction less than a size in the width direction of the first segment, the width direction being orthogonal to the stacking direction.

7. The semiconductor package of claim 6, wherein
the protrusion further comprises a hook protruding in a direction intersecting the stacking direction, and
the aperture has an insertion through which the hook is inserted along the stacking direction and a coupling with which the hook is engaged.

8. The semiconductor package of claim 7, wherein
the substrate includes a plurality of layer members superimposed in the stacking direction and a through aperture defined through the plurality of layer members,
the insertion is a first portion of the through aperture and is defined in at least one of the plurality of layer members, and
the coupling is a second portion of the through aperture and is defined in at least another of the plurality of layer members.

9. The semiconductor package of claim 1, wherein, when viewed from a top surface side of the cover glass, the cover glass holder covers at least a portion of the wire.

10. The semiconductor package of claim 1, wherein the frame comprises:
a frame wall supported by the substrate and extending along the stacking direction;
the cover glass holder extending from a top end of the frame wall toward a central side of the substrate; and
a frame connection connecting the frame wall and the cover glass holder,
wherein the frame connection has a thickness greater than a thickness of the frame wall and a thickness of the cover glass holder.

11. The semiconductor package of claim 1, wherein the substrate defines a closed space together with the cover glass and the frame such that the semiconductor chip is accommodated in the closed space in a sealed manner.

12. The semiconductor package of claim 11, further comprising:
a substrate wiring line in the substrate; and
a ball grid array (BGA) structure comprising a solder ball, the solder ball being electrically coupled to the substrate wiring line and capable of mounting the substrate on a motherboard.

13. The semiconductor package of claim 12, wherein the semiconductor chip is an imaging device.

14. A semiconductor package, comprising:
a substrate;
a semiconductor chip on a top surface of the substrate and electrically connected to the substrate;
a wire connecting the substrate and the semiconductor chip;
a cover glass; and
a frame on the substrate and holding the cover glass on the substrate,
wherein the frame comprises a cover glass holder holding the cover glass,
wherein the cover glass is held on a bottom surface side of the cover glass holder,
wherein the cover glass holder comprises a rib that protrudes in a direction opposite to a stacking direction, and
wherein the cover glass holder holds the cover glass through an adhesion part, the adhesion part being closer than the rib to a central side of the substrate.

15. The semiconductor package of claim 14, wherein
the frame further comprises a protrusion protruding in the direction opposite to the stacking direction from a bottom surface of the cover glass holder,
the substrate has an aperture into which the protrusion is inserted, and
the protrusion is fixed to the substrate by an adhesion part in the aperture in a state where the protrusion is inserted into the aperture.

16. The semiconductor package of claim 15, wherein the protrusion comprises:
a first segment; and
a second segment lower than the first segment and on a lower side of the stacking direction, the second segment having a size in a width direction less than a size in the width direction of the first segment, the width direction being orthogonal to the stacking direction.

17. The semiconductor package of claim 16, wherein
the protrusion further comprises a hook protruding in a direction intersecting the stacking direction, and
the aperture has an insertion through which the hook is inserted along the stacking direction and a coupling with which the hook is engaged.

18. The semiconductor package of claim 17, wherein
the substrate includes a plurality of layer members superimposed in the stacking direction and a through aperture defined through the plurality of layer members,
the insertion is a first portion of the through aperture and is defined in at least one of the plurality of layer members, and
the coupling is a second portion of the through aperture and is defined in at least another of the plurality of layer members.

19. The semiconductor package of claim 14, wherein, when viewed from a top surface side of the cover glass, the cover glass holder covers at least a portion of the wire.

20. The semiconductor package of claim 14, wherein the frame comprises:
a frame wall supported with respect to the substrate and extending along the stacking direction;
the cover glass holder extending from a top end of the frame wall toward the central side of the substrate; and
a frame connection connecting the frame wall and the cover glass holder,
wherein the frame connection has a thickness greater than a thickness of the frame wall and a thickness of the cover glass holder.

21.-23. (canceled)
